(19) United States
(12) Patent Application Publication
(10) Pub. No.: US 2015/0214244 A1
(43) Pub. Date: Jul. 30, 2015

(54) STRUCTURE AND PROCESS TO DECOUPLE DEEP TRENCH CAPACITORS AND WELL ISOLATION

(71) Applicant: INTERNATIONAL BUSINESS MACHINES CORPORATION, Armonk, NY (US)

(72) Inventors: Herbert L. Ho, Cornwall, NY (US); Sivananda K. Kanakasabapathy, Niskayuna, NY (US); Rishikesh Krishnan, Poughkeepsie, NY (US); Kern Rim, Yorktown Heights, NY (US)

(73) Assignee: INTERNATIONAL BUSINESS MACHINES CORPORATION, Armonk, NY (US)

(21) Appl. No.: 14/166,155

(22) Filed: Jan. 28, 2014

(51) Int. Cl. H01L 27/12; H01L 27/08; H01L 21/324; H01L 21/306; H01L 21/762; H01L 49/02; H01L 27/02

(52) U.S. Cl. CPC H01L 27/1203; H01L 28/40; H01L 27/0805; H01L 27/0207; H01L 21/30604; H01L 21/76224; H01L 21/324

(57) ABSTRACT

Formation of deep trench capacitors and isolation structures are decoupled by completing the isolation structures prior to etching trenches for capacitors and forming capacitors therein or vice-versa. Such decoupling of the formation of these respective structures allows different materials to be used in the deep trench capacitors and the isolation structures such as use of low permeability or dielectric constant materials and/or low Young's modulus materials in isolation structures to provide reduced AC capacitive coupling across isolation structures and/or relief of stresses associated with use of high dielectric constant materials or metal-insulator-metal (MIM) structures in deep trench capacitors. Such decoupling also allows increased efficiency of use of reaction chambers for the deep trench capacitors and the isolation structures.

### FIELD OF THE INVENTION

The present invention generally relates to integrated circuits including dynamic memory and, more particularly, to stress relief in integrated circuits including dynamic memory using deep trench capacitors, especially of metal-insulator-metal (MIM) design and/or capacitors using a high dielectric constant (Hi-K) material.

### BACKGROUND OF THE INVENTION

Relatively large amounts of storage is generally required in programmable logic circuits and to support programmable digital processor circuits. Accordingly, such needs for large amounts of storage has driven the design of capacitors suitable for digital data storage to extremely sophisticated levels and scaling to extremely small sizes and integration densities such that many millions of such capacitors can be formed on a chip of reasonable size in dynamic random access memories (DRAMs, sometimes referred to as eDRAMs). Relatively large amounts of storage can also be formed on the same chip with relatively large amounts of logic circuitry such as is found in microprocessors where proximity of storage and logic can reduce signal propagation time and increase clock rates that can be employed.

Regardless of the type of integrated circuit in which such dynamic storage is formed, substantial amounts of logic is also required to selectively access individual storage capacitors or groups of storage capacitors and to determine the charge stored on them. For example, significant amounts of logic is required for selectively connecting a given capacitor to a data source or sense amplifier and selectively energizing the word lines and bit lines. Such logic is generally referred to as the support area of the memory which may also contain additional (e.g. processor) logic.

The storage capacitors which have one plate or storage node connected to a transistor which provides for selection of the capacitor to be written or read will generally have the other plate connected, through the substrate, to all of the other storage capacitors in the memory array or at least a given portion thereof, generally referred to as the array area of the memory. Therefore, it is necessary to provide DC isolation between array area(s) of the chip and the logic or support area(s) of the chip.

In the past, such isolation was formed as a deep trench-like recess enclosing the support area of the chip and was referred to as a moat while storage capacitors were formed in recesses extending for a lesser distance into the substrate. Therefore, the recesses for the moat and for the storage capacitors have substantially different topology and isolation could be provided by the moat even if the structure inside the moat was similar to that within the storage capacitors since the capacitor dielectric could be applied directly to the semiconductor substrate material surrounding the moat as well as in the capacitor recesses. The semiconductor substrate material would thus form a capacitor plate for the capacitor trenches as well as forming a dielectric layer to provide electrical insulation on the interior of the moat. Such a structure provided both convenience and economy since processing to form capacitors included processes which were common to the moat.

In an effort to provide improved performance of the capacitors, metal-insulator-metal (MIM) capacitor designs have recently been introduced in which metal or other conductive material is first deposited or a self-aligned silicide, referred to as a salicide, formed on the interior semiconductor surface of the capacitor recesses, followed by an insulator (preferably a high dielectric constant or “Hi-K” material having a dielectric constant above about eight) and a further metal layer and metal and/or semiconductor material fill.

However, forming the capacitor recesses and the recesses for isolation structures in the same process results in a very narrow process window due to the different geometries (e.g. depths, transverse dimensions, aspect ratio and “footprint”) of the two recesses. Perhaps more importantly, however, metal deposition or salicidation in the moat is a contaminant that compromises isolation. Further, use of Hi-K material and possibly a salicidation process within the capacitor deep trenches can stress the surrounding material and possibly cause crystal lattice dislocations in the substrate surrounding the capacitor deep trenches which form preferential paths for leakage of stored charge from the capacitors as well as distorting the chip and possibly altering electrical characteristics of transistors and other devices in the support area.

### SUMMARY OF THE INVENTION

It is therefore an object of the present invention to provide a process of integrated circuit manufacture in which the formation of capacitor deep trenches is decoupled from formation of the recesses for isolation structures.

It is another object of the invention to provide stress relief for the array area and to provide stress isolation as well as electrical isolation between the array and support areas of an integrated circuit including dynamic memory and avoid distortions that may require mask precorrection or high order wafer alignment (HOWA).

It is a further object of the invention to provide not only DC electrical isolation but also AC electrical and stress isolation of the array and support/logic areas of an integrated circuit.

In order to accomplish these and other objects of the invention, an integrated circuit is provided including a substrate having a predetermined bulk resistance, a logic/support area, at least two deep trench capacitors spaced from each other and extending into the substrate, a moat isolation structure located between the logic/support area and the deep trench capacitor and extending into the substrate farther than the deep trench capacitor whereby a conduction path below the isolation structure is at least one micron longer than a distance between the deep trench capacitors and wherein said materials in the moat isolation structure and the deep trench capacitor are different.

In accordance with another aspect of the invention, a method of forming an integrated circuit having a logic/support area, at least one deep trench capacitor and a moat isolation structure between the deep trench capacitor and the logic/support area is provided comprising, in order, steps of etching a deep trench in a substrate, forming a capacitor structure in the deep trench, etching a recess in a substrate surrounding the capacitor structure or logic/support area, and filling the recess with a material different from a material in the capacitor structure, wherein the step of filling the recess is completed prior to the step of etching the deep trench or the step of forming a capacitor structure.

In accordance with a further aspect of the invention, a method of forming an integrated circuit having a logic/support area, at least one deep trench capacitor and a moat isolation structure between the at least one deep trench capacitor and the logic/support area is provided comprising, in order, steps of etching a recess in a substrate surrounding the capacitor structure or the logic/support area, filling said recess with at least one insulating material, etching a deep trench in the substrate, and forming a capacitor structure in the deep trench comprising at least one material different from material filling said recess, wherein the step of forming a capacitor structure is completed prior to the step of etching the recess or the step of filling the recess.

### BRIEF DESCRIPTION OF THE DRAWINGS

The foregoing and other objects, aspects and advantages will be better understood from the following detailed description of a preferred embodiment of the invention with reference to the drawings, in which:

FIGS. 1, 2 and 3 are a sequence of cross-sectional views illustrating a method of fabrication of deep trench capacitors and a moat isolation structure in accordance with the invention, and

FIGS. 4 and 5 are a sequence of cross-sectional views illustrating an alternative and, generally, preferred method of fabrication of deep trench capacitors and a moat isolation structure in accordance with the invention.

### DETAILED DESCRIPTION OF A PREFERRED EMBODIMENT OF THE INVENTION

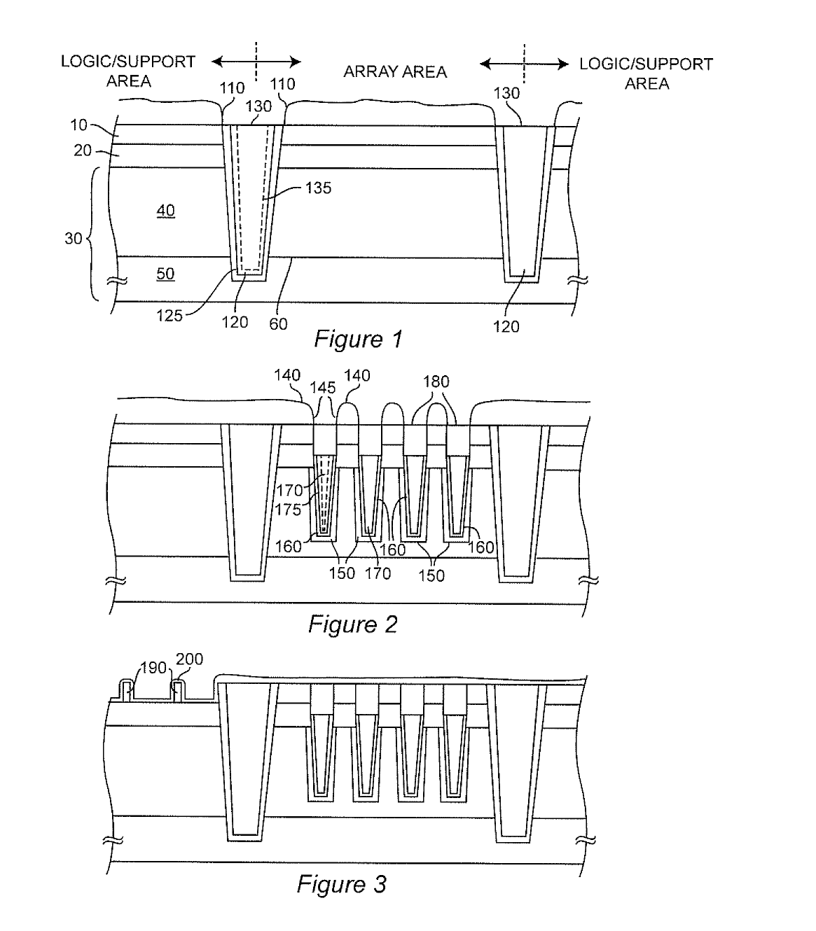

Referring now to the drawings, and more particularly to FIG. 1, there is shown a cross-sectional view of an initial stage of forming deep trench capacitors and a moat isolation structure in accordance with the invention. It is preferred to practice the invention using so-called semiconductor on insulator (SOI) wafer in which a layer of insulator 20 is formed on a so-called handling substrate 30 and a thin layer of semiconductor material 10 is formed over insulator 20 as the active semiconductor layer. However, the invention can be practiced using any type of substrate and is not limited to use with a SOI substrate as is assumed for clarity and simplicity in the following discussion. The insulator layer 20 is thus buried under active layer 10 and is thus generally referred to as a buried oxide (BOX), regardless of the material of which it is formed. The active layer in such a structure is often referred to a an SOI layer and is preferred since extremely high quality semiconductor can be provided in such a layer formed over an insulator.

When a large amount of dynamic memory is to be included in the integrated circuit to be formed on and in the wafer, at least the upper portion of the handling substrate is preferably highly doped (e.g. an impurity concentration of 10¹⁸/cm³ to 5×10²¹/cm³, preferably about 10₂₀/cm³) to have relatively low bulk resistance but a bulk resistance which is sufficiently high to allow adequate isolation to be achieved by extension of a moat isolation structure sufficiently below the level of the capacitor deep trenches to provide approximately one micron or more of additional conduction path length between the support/logic area and a deep trench capacitor than the spacing between deep trench capacitors. It is also possible but not necessary to the practice of the invention in accordance with its most basic principles to use a wafer in which the handling substrate is a composite structure, having a thick, highly doped (e.g. 10²⁰/cm³) and hence highly conductive layer 40 epitaxially grown on a substrate 50 which may be undoped but is preferably lightly and oppositely doped to form a diode junction at the interface 60 of substrate 50 and layer 40. Thus, the bulk resistance of layer 50 is relatively high and, in addition, since the isolation structure in the completed device extends into layer 50, will effectively present series-connected, oppositely poled diodes at the diode junctions on opposite sides of the isolation structure to provide enhanced electrical isolation.

The different sizes and shapes of the capacitor deep trenches and the recess for the isolation structure is evident from FIG. 2. As alluded to above, both recesses can be formed by a single set of lithography and etching processes even though the capacitor deep trenches do not extend as far into substrate 30 as the recess for the isolation structure and the recesses are of radically different sizes and shapes. The reason that such different depths and shapes can be achieved with a single etch process is that the transverse dimensions of the capacitor deep trenches is very much smaller than the transverse dimension of the recess for the isolation structure and the aspect ratio (e.g. ratio of width to depth) of the capacitor deep trenches will be very much less than the aspect ratio of the recess for the isolation structure at all times during the process and will increase with the duration of the etch and increasing depth of the respective recesses. (The capacitor deep trench will usually have a circular or oval shape in plan view while the isolation structure, in plan view, will have a shape similar to that of a closed polygon to surround an area to be electrically isolated. Therefore the effective aspect ratio of the trench for the isolation structure will be very much lower than is evident from the Figures since the trench extends for a substantial distance in front and in back of the plane of the cross-sections illustrated.)

A small transverse dimension and lower aspect ratios of recesses (which decrease rapidly as the capacitor deep trenches are etched to greater depths) tends to restrict circulation of etchant near the etching reaction frontier and the etchant thus becomes somewhat diluted by loading of removed material, causing the etching process to proceed more slowly relative to the etching in the trench or recess for the isolation structure and the difference in etch rate will increase as the etching process proceeds.

Nevertheless, the depths of the capacitor deep trenches and the recess or trench for the isolation structure are quite critical since the difference in depth must provide a sufficiently increased conduction path length for adequate isolation. If a composite handling substrate as described above is used, the capacitor deep trenches must remain within the highly doped layer 40, particularly if a surface of that layer within the deep trench forms a capacitor plate (as is the case, for example, if the inner surface of the capacitor deep trenches is silicided) as well as providing common capacitor plate connections through that layer while the trench or recess for the isolation structure must extend into the layer 50 so that high resistance and/or back-to-back diodes is presented under and adjacent to the isolation structure. Therefore, the process parameter tolerance window is relatively small for forming both deep trenches concurrently with a single etch process, regardless of how desirable concurrent formation might be from the standpoint of process time, process simplicity and/or cost. On the other hand, the process parameter tolerance window is sufficient that manufacturing yield is not compromised to any significant degree sufficient, in and of itself, to justify decoupling the formation of the two types of trenches even though concurrent trench formation generally implies that some materials used in isolation structures will be the same as some materials used in the capacitors.

However, as alluded to above, some materials and processes that may be preferred for use in the deep trench (e.g. MIM) capacitors are contaminants in the moat isolation structures and compromise their isolation functions as well as having been found to cause stress in the crystal lattice structure of epitaxially grown layer 40. Some residual stress will exist in layer 40 simply due to the presence of a high concentration of impurities in that layer as alluded to above. Therefore, layer 40 may have a somewhat increased susceptibility to crystal lattice defects and dislocations occurring at relatively low additional levels of stress. Such additional levels of stress can easily be caused when materials that cause stress in the deep trench capacitors such as Hi-K materials and silicide alloy formation are also deposited in the isolation structures.

Thus, in accordance with the invention, decoupling of the formation of the isolation structures and the deep trench capacitors, including the etching of respective trenches therefor, is provided and justified by the ability to place material in the isolation structures that relieves the stresses developed in the capacitors of the array area of the chip as well as increasing process parameter tolerance windows for the respective etch processes; allowing the capacitors and isolation structures to be formed with greater freedom of design and dimensional precision. Decoupling of the formation of capacitor and isolation structures also allows different fill materials to be employed with some reduction in process complexity compared to manufacture of a device where both types of recesses concurrently exist at the beginning of processes for filling the respective recesses, particularly where MIM capacitors are to be formed. In particular, decoupling of the moat isolation and deep trench capacitors allows a low permeability or low dielectric constant (low-K) material to be used in the moat isolation structure to enhance electrical isolation at high frequencies that might otherwise be capacitively coupled across the moat as well as use of a soft material having a low Young's modulus of elasticity to provide mechanical isolation of stresses that may be developed in the array area of an integrated circuit.

Returning now to FIG. 1, a first method of manufacturing deep trench capacitors and isolation structures will now be described. Beginning with an SOI wafer as described above, a mask 110 such as a resist or trulayer mask system is applied and patterned and a deep recess 120 is etched through the SOI layer 10, BOX layer 20 and highly doped layer 40 and into layer 50 for a distance sufficient to assure adequate depth throughout the entirety of all isolation structures. The deep recess 120 is preferably etched using a NF₃/HBr/O₂ chemistry but is not restricted to such an etching process. Other options include SF₆/CH₂F₂ process or a HBrO₂ process but the latter is not preferred. An optional liner 125 of an insulating material such as silicon oxide or silicon nitride can then be deposited and the recess filled as shown at 130, preferably with an insulator, but a semiconductor material can be used for fill if optional liner 125 is deposited, with or without removal of mask 110. Allowing mask 110 to remain is preferred since it provides protection to the remaining areas of the active layer 10 and, when later removed, ensures removal of liner or fill material that is deposited on it during the fill process. If the mask is removed during the fill operation(s), the upper surface of the wafer is preferably planarized (e.g. by chemical/mechanical polishing) to the active layer 110.

It should be appreciated that a relatively wide variety of materials and structures can be formed during filling of the moat isolation structure. For example, a tensile, neutral or compressive oxide, nitride or other material or a sequence of tensile, neutral and/or compressive films of oxide, nitride or other materials can be chosen to be complementary to anticipated stresses that will be developed when the capacitors are formed of particular materials. Alternatively or in combination therewith, a material having a Young's modulus of elasticity lower than that of silicon or other semiconductor material of the substrate can be used as isolation for stresses developed in the array area. High order wafer alignment (HOWA) and need for mask precorrection to accommodate wafer distortion can thus be reduced or avoided. As alluded to above, low permeability or low-K materials can be employed alone or in combination with other materials or structures to increase or provide AC electrical isolation, particularly at high frequencies. Materials suitable for shallow trench isolation (STI) may also be used. Any or all of these possible structures are schematically and collectively illustrated by dashed line 135. The moat isolation structures are then completed by annealing to relieve residual stresses that may have developed in the substrate. Annealing at this point in the process before capacitors are formed also avoids the exposure of the capacitors to the high temperature of the annealing process. However, depending on the structure and materials of the moat isolation structure, annealing may be optional but will be beneficial for most materials and structures.

Then, as illustrated in FIG. 2, another mask (e.g. resist but, preferably, a more durable sacrificial oxide or nitride pad film to provide a hard mask) layer 140 is applied and patterned (e.g. using a resist or trilayer mask system) to define the capacitor deep trenches 145. So-called split pitch lithography is preferably employed for recess shape and critical dimension accuracy in view of the desirable close spacing of the capacitor deep trenches at extreme scaling. The capacitor deep trenches can then be etched through active layer 10 and BOX layer 20 and into layer 40 to a depth preferably only slightly less than the thickness of highly doped layer 40 so that maximum area and capacitance can be developed with substantial uniformity among the capacitor deep trenches. A NF₃/Hbr/O₂ chemistry process in a capacitive discharge is preferred but other etching processes, such as those alluded to above, can be used. As alluded to above, the etching process will proceed more slowly as the trench depth increases; tending to improve uniformity of depth if the openings in mask 140 are also highly uniform.

Once the capacitor deep trenches have been formed in conductive layer 40, metal or other highly conductive material can optionally be deposited as a liner in the deep trenches. There will be no deposition of conductive material in the moat to compromise the isolation function since the moat has already been filled, as described above. If such metal or conductive material is deposited in the deep trenches, a heat treatment may optionally be performed to form a silicide in the walls of the deep trench, as depicted at 150. Next, a capacitor dielectric 160, preferably a Hi-K material, is deposited within the deep trenches and the remainder of the deep trenches filled with conductive material such as metal or (doped) polysilicon 170, with or without an optional conductive liner 175 (illustrated only in the left-most capacitor, for clarity) to form the other capacitor plate which will function as a storage node. The fill material 170 and the dielectric 160 is then preferably etched back to a depth within the BOX layer 20 and the upper portion of the trench re-filled with polysilicon or metal 180 and planarized. The integrated circuit can then be completed by processing the active layer to form transistors, preferably as finFETs 190 patterned by sidewall image transfer (SIT), in the support and array areas and forming bit line and word line connections 200.

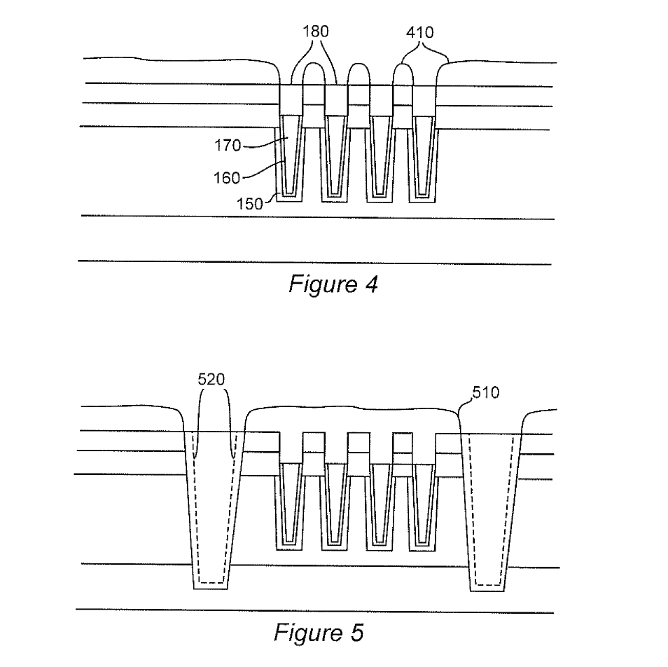

It should be understood that the embodiment of the invention described above where the moat isolation is completed prior to capacitor formation is preferred since damage to the moat isolation is unlikely to be caused by the processing for capacitor formation and overlay error tolerance is somewhat greater. The above-described embodiment is also necessary where the heat budget for moat isolation material annealing or other processes or materials required for moat formation such as shallow trench isolation high aspect ratio process (STI HARP) oxide is not compatible with the heat budget for the capacitors. However, the invention may also be practiced by forming the deep trench capacitors before formation of the moat isolation where the heat budgets of capacitor formation and moat isolation are, in fact, compatible as will now be described with reference to FIGS. 4 and 5.

Referring first to FIG. 4, a preferred SOI wafer as described above has a resist or, preferably, a hard mask 410 of sacrificial nitride or oxide applied thereto and patterned. As before, split pitch lithography is preferred for high accuracy of shape and critical dimensions in patterning. The capacitor deep trenches are then etched as described above and optional liner or silicide 150, dielectric 160, optional conductive liner 175, conductive fill 170 and storage node cap 180 applied as described above. Then, hard mask 410 is removed and the array area covered with a block-out mask 510 which is patterned at the location(s) desired for the moat isolation structure as illustrated in FIG. 5. The trenches for the moat isolation structure are then etched and insulating material deposited in the trench. Any of the materials or combinations of materials described above can be used as collectively indicated by dashed line 520. Annealing can be and is preferably performed at this stage to relieve stresses that may have developed in the array area. The annealing can also repair any lattice damage in the array and/or support areas that may have occurred due to stresses developed during capacitor formation. The integrated circuit is then completed as described above in connection with FIG. 3.

In view of the foregoing, it is clearly seen that decoupling of the formation of moat isolation structures and deep trench capacitor formation, while counter-intuitive from the standpoint of process cost and complexity, provides wide process parameter windows to increase manufacturing yield and can provide relief of stresses that may occur in the array area of a chip, improving reliability and avoidance of preferential charge leakage paths in the array area and alteration of electrical characteristics of elements formed in the support area on an integrated circuit. The manufacturing process is, in fact, simplified by avoidance or reduction of requirements for predistortion of mask patterns or prestressing of areas of the integrated circuit (which can, at best, provide only an approximated correction of distortions or stresses) and provides complete freedom of design of both storage capacitors and moat isolation structures. The cost of decoupling the formation of moat isolation structures and deep trench structures is also limited by the fact that comparatively high cost apparatus required for fine, closely spaced capacitor deep trench formation is not required for the much larger and relatively coarse features of the moat.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. An integrated circuit including
a substrate having a predetermined bulk resistance,
a logic/support area,
at least two deep trench capacitors spaced from each other and extending into said substrate,
a moat isolation structure located between said logic/support area and said deep trench capacitor, said moat isolation structure extending into said substrate farther than said deep trench capacitor whereby a conduction path below said isolation structure is at least one micron longer than a distance between said at least two deep trench capacitors and wherein said materials in said moat isolation structure and said deep trench capacitor are different.

2. An integrated circuit as recited in claim 1, wherein said at least two deep trench capacitors include a conductive lining in deep trenches but no conductive lining is included in said moat isolation structure.

3. An integrated circuit as recited in claim 2, wherein said conductive lining comprises a metal.

4. An integrated circuit as recited in claim 2, wherein said conductive lining comprises a silicide.

5. An integrated circuit as recited in claim 1, wherein said moat isolation structure includes a dielectric liner

6. An integrated circuit as recited in claim 5, wherein said moat isolation structure is filled with dielectric material.

7. An integrated circuit as recited in claim 5, wherein said moat isolation structure is filled with semiconductor material.

8. An integrated circuit as recited in claim 5, wherein said moat isolation structure is filled with shallow trench isolation material.

9. An integrated circuit as recited in claim 1, wherein said moat isolation structure is filled with dielectric material.

10. An integrated circuit as recited in claim 1, wherein said moat isolation structure is filled with semiconductor material.

11. An integrated circuit as recited in claim 1, wherein said moat isolation structure is filled with shallow trench isolation material.

12. An integrated circuit as recited in claim 1, wherein said at least two deep trench capacitors include a layer of high dielectric constant material.

13. An integrated circuit as recited in claim 12 wherein said at least two deep trench capacitors are filled with metal, semiconductor material or silicide.

14. An integrated circuit as recited in claim 1, wherein said at least two deep trench capacitors and said moat isolation structure are formed in an SOI structure having a composite handling substrate comprising a bulk semiconductor layer and a highly doped semiconductor layer formed over said bulk semiconductor layer wherein said at least two deep trench capacitors extend into said highly doped semiconductor layer but not said bulk semiconductor layer and said moat isolation structure extends through said highly doped semiconductor layer and into said bulk semiconductor layer.

15. An integrated circuit as recited in claim 14, wherein series connected, oppositely poled diodes are formed adjacent said moat isolation structure.

16. A method of forming an integrated circuit having a logic/support area, at least one deep trench capacitor and a moat isolation structure between said at least one deep trench capacitor and said logic/support area, said method comprising, in order, steps of
etching a deep trench in a substrate,
forming a capacitor structure in said deep trench,
etching a recess in a substrate surrounding one of said capacitor structure and said logic/support area, and
filling said recess with a material different from any material in said capacitor structure, wherein said step of filling said recess is completed prior to said step of etching said deep trench or said step of forming a capacitor structure.

17. The method as recited in claim 16 including a further step of
forming an insulating liner in said recess.

18. A method of forming an integrated circuit having a logic/support area, at least one deep trench capacitor and a moat isolation structure between said at least one deep trench capacitor and said logic/support area, said method comprising, in order, steps of
etching a recess in a substrate surrounding one of said capacitor structure and said logic/support area,
filling said recess with at least one insulating material,
etching a deep trench in said substrate, and
forming a capacitor structure in said deep trench, said capacitor structure comprising at least one material different from material filling said recess, wherein said step of forming a capacitor structure is completed prior to said step of etching said recess or said step of filling said recess.

19. The method as recited in claim 18, including the further step of
forming an insulating liner in said recess.

20. The method as recited in claim 18, further comprising a step of annealing following said step of filling said recesses.
